(19) United States
(12) Patent Application Publication
(10) Pub. No.: US 2009/0284158 A1
(43) Pub. Date: Nov. 19, 2009

(54) ORGANIC LIGHT EMITTING DEVICE BASED LIGHTING FOR LOW COST, FLEXIBLE LARGE AREA SIGNAGE

(75) Inventors: Gautam Parthasarathy, Saratoga Springs, NY (US); Svetlana Rogojevic, Niskayuna, NY (US); Thomas Shaginaw, Burnt Hills, NY (US)

Correspondence Address: GENERAL ELECTRIC COMPANY;GLOBAL RESEARCH, PATENT DOCKET RM. BLDG. K1-4A59, NISKAYUNA, NY, 12309, US

(73) Assignee: GENERAL ELECTRIC COMPANY, Schenectady, NY (US)

(21) Appl. No.: 12/122,429

(22) Filed: May 16, 2008

(51) Int. Cl. H05B 37/02; H01L 27/32; H01J 9/02

(52) U.S. Cl. 315/169.3; 313/504; 445/24

(57) ABSTRACT

The present techniques provide light emitting assemblies that include two or more light emitting devices joined into a single multilayered structure. Each device is electrically contiguous, and includes an electroluminescent polymer layer between two electrodes. In each device, the electroluminescent polymer layer and/or at least one of the two electrodes is patterned to form an illuminated design. Each device may be separately energized to illustrate a different pattern or design. In some embodiments, a layer having a contiguous light emitting layer may be attached to the back of the multilayer structure.

### BACKGROUND

The present techniques relate generally to large area displays formed from organic light emitting materials. Specifically, the present techniques provide methods for making patterned signs from such materials.

This section is intended to introduce the reader to aspects of art that may be related to aspects of the present techniques, which are described and/or claimed below. This discussion is believed to be helpful in providing the reader with background information to facilitate a better understanding of the various aspects of the present techniques. Accordingly, it should be understood that these statements are to be read in this light, and not as admissions of prior art.

A developing trend in circuit and display technology involves the implementation of electronic and opto-electronic devices that take advantage of electroluminescent organic materials. These devices provide low cost, high performance alternatives to silicon electronic devices and to traditional lighting. One such device is the organic light emitting diode (OLED). OLED's are solid-state semiconductor devices, which implement organic semiconductor layers to convert electrical energy into light. Generally, OLEDs are fabricated by disposing multiple layers of thin films that include electroluminescent organic materials between two conductors or electrodes. The electrode layers and the organic layers are generally disposed on one substrate or between two substrates, such as glass or plastic. The OLEDs operate by accepting charge carriers of opposite polarities, electrons and holes, from the electrodes. An externally applied voltage drives the charge carriers into the recombination region to produce light emissions. Unlike many silicon based devices, OLEDs can be processed using low cost, large area thin film deposition processes which allow for the fabrication of ultra-thin, light weight lighting displays. Significant developments have been made in providing general area lighting implementing OLEDs.

Large area OLED devices typically combine many individual OLED devices on a single substrate or a combination of substrates with multiple individual OLED devices on each substrate. Groups of OLED devices are typically coupled in series and/or parallel to create an array of OLED devices which may be employed in display, signage or lighting applications, for instance. For these large area applications, it may be desirable to create large light emitting areas in the array while minimizing the areas that do not produce light.

However, while the combination of many interconnected devices in each substrate layer may increase the reliability of a large area OLED device, it will generally limit the minimum size of an individual feature. This may provide a coarse point or “pixel” that may make the production of individual fine features in a sign or picture difficult to display. Furthermore, the interconnections may increase the cost of a display panel, which may make it impractical for low end applications. Similarly, a pixilated display having fine features may be made from individually addressable points, connected in either a passive or an active matrix, but the complexity of the resulting panel and, thus, the cost, may limit the use to high end applications.

### BRIEF DESCRIPTION

One embodiment of the present techniques provides a light emitting assembly, that includes two or more devices joined into a layered structure. Each device may be individually illuminated, and each device includes a bottom electrode that is electrically contiguous, a layer including an electroluminescent organic material in electrical contact with the bottom electrode, and a top electrode, which is also electrically contiguous and in electrical contact with the layer. At least one of the bottom electrode, any component of the layer that includes the electroluminescent organic materials, or the top electrode is physically or chemically patterned to form a design configured to be illuminated.

Another embodiment provides a method for manufacturing a display The method includes forming two or more light emitting devices, wherein each of the two or more light emitting devices is configured to be individually energized In each device, at least one of an anode, a cathode, or a component of a layer that includes an electroluminescent material is chemically or physically patterned to form a design. The two or more devices may be joined in a vertical fashion to form a multilayer structure.

Another embodiment provides a system that includes an electrical control and power unit and two or more light emitting layers configured to be independently illuminated by the electrical control and power unit. Each of the two or more light emitting layers includes an electrically contiguous bottom electrode, a layer including an electroluminescent organic material in electrical contact with the bottom electrode, and a top electrode, wherein the top electrode is electrically contiguous and in electrical contact with the layer including the electroluminescent organic material. At least one of the bottom electrode, a component of the layer comprising the electroluminescent organic material, or the top electrode is chemically or physically patterned to form a design configured to be illuminated.

Another embodiment provides a device that includes a multilayer panel. The multilayer panel includes two or more light emitting layers. Each of the two or more light emitting layers includes one or more electroluminescent organic materials is a single unit that is electrically contiguous across the entire layer each layer may have a different design or color with respect to each of the other layers. The system may also include a controller providing power to individually energize each layer of the multilayer panel.

### DRAWINGS

These and other features, aspects, and advantages of the present invention will become better understood when the following detailed description is read with reference to the accompanying drawings in which like characters represent like parts throughout the drawings, wherein:

FIG. 1 is a drawing showing an example of a sign having multiple layers that display the same information in different languages, in accordance with an embodiment of the present techniques;

FIG. 2 is a exploded view of the sign of FIG. 1, showing the individual layers, in accordance with an embodiment of the present techniques;

FIG. 3 is cross sectional view of the sign of FIG. 1, illustrating the layers that may form the individual devices, in accordance with an embodiment of the present invention;

FIG. 4 is a front view of a single device, illustrating the use of patterns made in the electroluminescent organic material and one of the electrically contiguous electrodes to form illuminated patterns, in accordance with an embodiment of the present techniques;

FIG. 5 is a cross sectional view of a complete device, hermetically sealed and coupled to a power supply/control unit, in accordance with an embodiment of the present techniques;

FIG. 6 is a chart of transmission versus wavelength for varying thicknesses of cathode layers, with and without an anode layer, in accordance with embodiments of the present techniques;

FIG. 7 is a chart of current density versus voltage for varying thicknesses of cathode layers, in accordance with embodiments of the present techniques; and

FIG. 8 is a chart of the efficiency (in Watts light emitted/Watts electricity applied) versus the current density for a blue light emitting polymer using varying thicknesses of cathode layers, in accordance with embodiments of the present techniques.

### DETAILED DESCRIPTION

One or more specific embodiments of the present invention will be described below. In an effort to provide a concise description of these embodiments, not all features of an actual implementation are described in the specification. It should be appreciated that in the development of any such actual implementation, as in any engineering or design project, numerous implementation-specific decisions must be made to achieve the developers' specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

### Introduction

The present techniques include systems and methods for displaying information from multiple light emitting layers that may be illuminated either individually or simultaneously. Each light emitting layer is a separate device containing electroluminescent organic materials that may be disposed between a lower positive electrode, or anode, and an upper negative electrode, or cathode. The electroluminescent organic materials function as organic semiconductors, forming an organic light emitting diode (OLED) having a large surface area. Furthermore, while both the electroluminescent organic materials and one or both electrodes may be patterned to form the information, each electrode is electrically contiguous, making each device a single OLED. This may result in a relatively low cost panel, as no complex schemes are required for interconnecting multiple devices in each layer.

An exemplary device in accordance with the present techniques is illustrated in FIG. 1. One of ordinary skill in the art will recognize that this example merely illustrates one possible configuration and that any number of other configurations may be used. As shown in FIG. 1, a sign 10 has a layer containing a first message 12 in a first language. In the illustration, the first message 12 is illuminated and, thus, visible from the front of the panel. The sign 10 may also have additional layers. In the example in FIG. 1, a second layer has a second message 14, illustrated by dashed lines, and a third layer has a third message 16, illustrated by dotted lines. Generally, the additional layers will not be visible unless energized, making it possible to illuminate a specific message for a specific person or group.

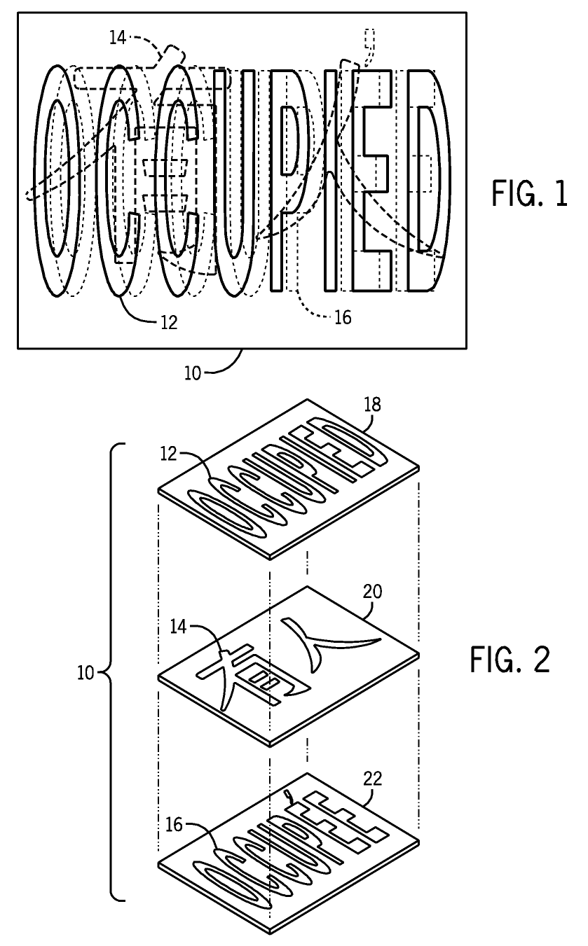

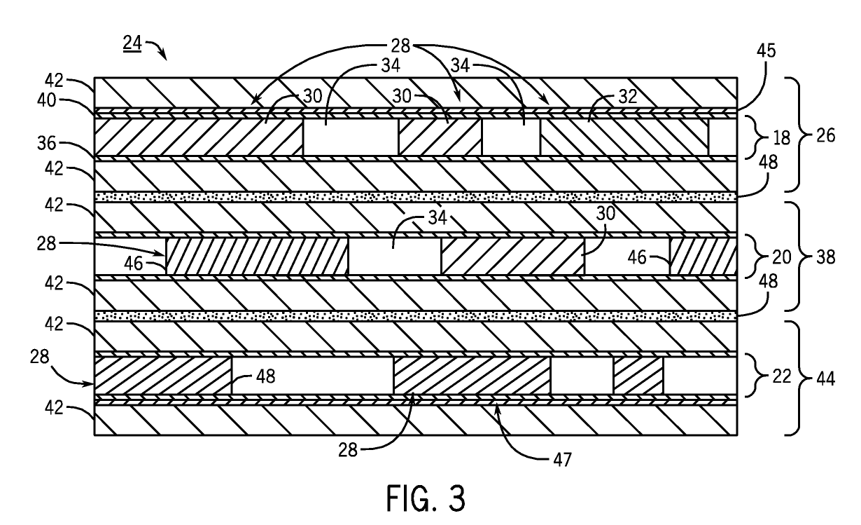

The use of different layers in conveying different information is further illustrated by the exploded view of FIG. 2. As shown in FIG. 2, the first layer 18 containing the first message 12 is joined to the second layer 20 containing the second message 14, and the third layer 22, containing the third message 16. Each layer is contained in an individual OLED device, as discussed further with respect to FIG. 3, below. One of ordinary skill in the art will recognize that the techniques are not limited to three layers. Indeed, any number of layers may be included so long as a sufficient amount of light from the lower layers is transmitted to the viewer.

Further, the use of multiple layers containing different designs may allow for any number of other effects useful to enhance communications, for example, using different layers that have different parts of a single message or design that may be individually or simultaneously illuminated. For example, an illuminated sign may have a corporate logo on one layer, and the words “open” and “closed” on successive layers. In this example, the layer containing the logo may be configured to be continuously illuminated, while the other layers may be separately illuminated to indicate the current operational status of a business.

Furthermore, the emission color of the electroluminescent organic materials used in each of the different layers may be the same or may be different, for example, using different colors to convey messages from different layers. Further, any single layer may contain multiple colors, although all parts of any single layer, as a single device, will be simultaneously illuminated. The wide varieties of choices that are possible for the designs and colors on each layer make the present techniques an effective and relatively low cost tool for the creation of signs, illustrations, displays, or other decorative or informational uses.

### Devices and Materials

FIG. 3 is a cross sectional view of a multilayer structure 24, which may contain layers having different messages, for example, as discussed with respect to FIGS. 1 and 2, above. The multilayer structure 24 includes a first device 26, a second device 38 and a third device 44 arranged in a standard configuration. In FIG. 3, the first layer 18 is an illuminated layer in a first device 26. The first device 26 has electroluminescent organic materials 28 deposited into patterned regions to form a design, for example, the first message 12 shown in FIGS. 1 and 2. The electroluminescent organic materials 28 do not have to be the same across the first layer 18. For example, the electroluminescent organic materials 28 in the illustration may include a first electroluminescent organic material 30 and a second electroluminescent organic material 32, if, for example, two different colors are desired within the first layer 18. One of ordinary skill in the art will recognize that any number of colors may be used in a single layer. Further, non-light emitting materials (not shown) may be included in layers containing the electroluminescent organic materials 28 to improve the light emitting efficiency or operational lifespan of the emitting layers. In order to form patterns, the first layer 18 may also include one or more inactive zones 34 which do not emit light. These inactive zones 34 may be filled with an inert material used to prevent short circuits in the device. Such inert materials may include plastics, such as those used for the substrates, as discussed below, or may include inactive materials that are similar in structure to the electroluminescent organic materials 28 as discussed below.

In contrast to the technique described above, in other embodiments, a layer comprising a single electroluminescent organic material may be deposited across the entire device 26, and other techniques may be used to form the light emitting pattern. For example, a hole transport material (as discussed in further detail below) that includes a chemical dopant may be used adjacent to the electroluminescent organic materials 28. The chemical dopant may be light activated, e.g., forming products upon irradiation with ultraviolet (UV) light. These products may then react with, or dope, the hole transport material at the points of irradiation to allow the hole transport material to conduct electricity to the electroluminescent organic materials 28. In effect, the pattern would be drawn on the device by exposure to UV light.

Another technique that may be used to form a light emitting pattern in the electroluminescent organic materials 28 may use UV light to degrade the electroluminescent organic materials 28 and, thus, deactivate them. For example, the electroluminescent organic materials 28 may include chemical dopants that form products upon irradiation which may break down the light emitting capability of the electroluminescent organic materials 28. In this embodiment, the device would be dark at the points of the irradiation, creating a negative image of the irradiation pattern.

In still another embodiment, after electroluminescent organic materials 28 are deposited over an anode, an insulating layer may be deposited in a pattern over the electroluminescent organic materials 28 prior to the deposition of a cathode, as discussed below. The patterned insulating layer would block current flow in areas where it was deposited creating an illuminated pattern in areas where the insulating materials were not deposited. This technique would create an illuminated negative image of the deposited pattern.

Any number of electroluminescent organic materials 28 that emit light upon electrical stimulation (i.e., are electroluminescent) may be used in the current techniques. For example, such materials may include electroluminescent organic materials 28 that may be tailored to emit light in a determined wavelength range. The thickness of an electroluminescent layer may be greater than about 40 nanometers or may be less than about 300 nanometers. The electroluminescent organic materials 28 may include polymers, copolymers, or a mixture of polymers. For example, suitable electroluminescent organic materials 28 may include poly N-vinylcarbazole (PVK) and its derivatives; polyfluorene and its derivatives, such as polyalkylfluorene, for example poly-9,9-dihexylfluorene, polydioctylfluorene, or poly-9,9-bis-3,6-dioxaheptyl-fluorene-2,7-diyl; polypara-phenylene and its derivatives, such as poly-2-decyloxy-1,4-phenylene or poly-2,5-diheptyl-1,4-phenylene; polyp-phenylene vinylene and its derivatives, such as dialkoxy-substituted PPV and cyano-substituted PPV; polythiophene and its derivatives, such as poly-3-alkylthiophene, poly-4,4′-dialkyl-2,2′-bithiophene, poly-2,5-thienylene vinylene; polypyridine vinylene and its derivatives; polyquinoxaline and its derivatives; and polyquinoline and its derivatives.

In one embodiment, a suitable electroluminescent material is poly-9,9-dioctylfluorenyl-2,7-diyl end capped with N,N-bis4-methylphenyl-4-aniline. Mixtures of these polymers or copolymers based on one or more of these polymers may be used.

Other suitable materials that may be used as electroluminescent organic materials 28 are polysilanes. Polysilanes are linear polymers having a silicon-backbone substituted with an alkyl and/or aryl side groups. Polysilanes are quasi one-dimensional materials with delocalized sigma-conjugated electrons along polymer backbone chains. Examples of polysilanes include poly di-n-butylsilane, poly di-n-pentylsilane, poly di-n-hexylsilane, polymethyl phenylsilane, and poly bis p-butyl phenylsilane.

In one embodiment, organic materials having molecular weight less than about 5000, including aromatic units, may be used as the electroluminescent organic materials 28. An example of such materials is 1,3,5-tris[N-(4-diphenyl aminophenyl) phenylamino] benzene, which emits light in the wavelength range of from about 380 nanometers to about 500 nanometers. These electroluminescent organic materials 28 may be prepared from organic molecules such as phenylanthracene, tetraarylethene, coumarin, rubrene, tetraphenylbutadiene, anthracene, perylene, coronene, or their derivatives. These materials may emit light having a maximum wavelength of about 520 nanometers. Still other suitable materials are the low molecular-weight metal organic complexes such as aluminum-acetylacetonate, gallium-acetylacetonate, and indium-acetylacetonate, which emit light in the wavelength range of about 415 nanometers to about 457 nanometers, aluminum picolymethylketone bis-2,6-dibutylphenoxide or scandium-4-methoxy picolyl methyl ketone-bis acetyl acetonate, which emit light having a wavelength in a range of from about 420 nanometers to about 433 nanometers. Other suitable electroluminescent organic materials 28 that emit in the visible wavelength range may include organo-metallic complexes of 8-hydroxyquinoline, such as tris-8-quinolinolato aluminum and its derivatives.

The electroluminescent organic materials 28 may have one or more non-emissive materials in layers adjoining the electroluminescent organic materials 28. These non-emissive materials may, for example, improve the performance or lifespan of the electroluminescent materials. The non-emissive materials may include, for example, a charge transport layer, a hole transport layer, a hole injection layer, a hole injection enhancement layer, an electron transport layer, an electron injection layer and an electron injection enhancement layer or any combinations thereof.

Non-limiting examples of materials suitable for use as charge transport layers may include low-to-intermediate molecular weight organic polymers, for example, organic polymers having weight average molecular weights of less than about 200,000 grams per mole as determined using polystyrene standards. Such polymers may include, for example, poly-3,4-ethylene dioxy thiophene (PDOT), polyaniline, poly-3,4-propylene dioxythiophene (PPropOT), polystyrene sulfonate (PSS), polyvinyl carbazole (PVK), and other like materials.

Non-limiting examples of materials suitable for the hole-transport layer may include triaryldiamines, tetraphenyldiamines, aromatic tertiary amines, hydrazone derivatives, carbazole derivatives, triazole derivatives, imidazole derivatives, oxadiazole derivatives including an amino group, polythiophenes, and like materials. Non-limiting examples of materials suitable for a hole-blocking layer may include poly N-vinyl carbazole, and like materials.

Non-limiting examples of materials suitable for hole-injection layers may include proton-doped (i.e., “p-doped”) conducting polymers, such as p-doped polythiophene or polyaniline, and p-doped organic semiconductors, such as tetrafluorotetracyanoquinodimethane (F4-TCQN), doped organic and polymeric semiconductors, and triarylamine-containing compounds and polymers. Non-limiting examples of electron-injection materials may include polyfluorene and its derivatives, aluminum tris-8-hydroxyquinoline (Alq3), organic/polymeric semiconductors n-doped with alkali alkaline earth metals, and the like.

Non-limiting examples of materials suitable for a hole injection enhancement layer may include arylene-based compounds such as 3,4,9,10-perylene tetra-carboxylic dianhydride, bis-1,2,5-thiadiazolo-p-quino bis-1,3-dithiole, and like materials.

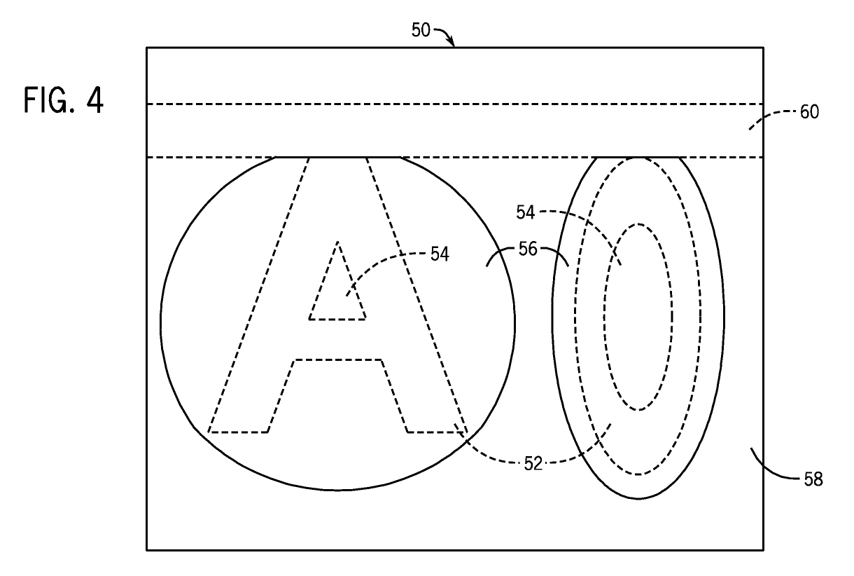

The first device 26 also has a lower electrode, or anode 36. The anode 36 is electrically contiguous across the first device 26, forming a single unit. Although the anode 36 is electrically contiguous, it may be deposited in a pattern, as discussed with respect to FIG. 4, below. Generally, materials used for the anode 36 may have a high work function, e.g., greater than about 4.0 electron volts. Suitable materials may include, for example, indium tin oxide (ITO), tin oxide, indium oxide, zinc oxide, indium zinc oxide, zinc indium tin oxide, antimony oxide, and mixtures thereof. The thickness of an anode that includes such an electrically conducting oxide may be greater than about 10 nanometers. In one embodiment, the thickness may be in the range of from about 10 nanometers to about 50 nanometers, from about 50 nanometers to about 100 nanometers, or from about 100 nanometers to about 200 nanometers.

A thin transparent layer of a metal may also be used as the anode 36. Such a metal layer may have a thickness, for example, of less than or equal to about 50 nanometers. In one embodiment, the metal thickness may be in a range of from about 50 nanometers to about 20 nanometers. Suitable metals for the anode 36 may include, for example, silver, copper, tungsten, nickel, cobalt, iron, selenium, germanium, gold, platinum, aluminum, or mixtures thereof or alloys thereof. The anode 36 may be deposited on the underlying element by a technique such as physical vapor deposition, chemical vapor deposition, sputtering, or liquid coating.

One type of anode 36 that may be used in embodiments of the present techniques is formed from a deposited layer of indium-tin-oxide (ITO) between about 60 and 150 nm in thickness. The ITO layer may be about 60 to 100 nm in thickness, or may be about 70 nm thick. The thickness of the anode 36 is determined by the balance between the transparency and the conductivity. A thinner anode 36 may be more transparent, allowing more light from lower layers to be passed through. In contrast, a thicker anode 36, may block more light, but have improved conductivity, increasing the lifespan of the first device 26. The thickness of the anode 36 may also depend on the location in a multilayer structure 24. For example, an anode 36 in the first device 26 may be made thinner than an anode in, for example, the second device 38.

The first device 26 also has an upper electrode, or cathode 40. As in the case of the anode 36, the cathode 40 may be deposited in a pattern to form a design, as discussed with respect to FIG. 4, below. The cathode 40 is generally made from metallic materials having a low work function, e.g., less than about 4 electron volts, although not every material suitable for use as the cathode need have a low work function. Materials suitable for use as the cathode may include K, Li, Na, Mg, Ca, Sr, Ba, Al, Ag, In, Sn, Zn, Zr, Sc, and Y. Other suitable materials may include elements of the lanthanide series, alloys thereof, or mixtures thereof. Examples of suitable alloy materials for the manufacture of cathode layer may include Ag—Mg, Al—Li, In—Mg, and Al—Ca alloys. Layered non-alloy structures may be used. Such layered non-alloy structures may include a thin layer of a metal such as Ca having a thickness in a range of from about 1 nanometer to about 50 nanometers. Other such layered non-alloy structures may include a non-metal such as LiF, KF, or NaF, over-capped by a thicker layer of some other metal, or n-doped polymers. A suitable other metal may include aluminum or silver. The cathode may be deposited on the underlying layer by, for example, physical vapor deposition, chemical vapor deposition, sputtering or liquid coating.

One material combination that may be used to form a very thin and, thus, more transparent, cathode 40 may have a first layer made from silver of about 7.5 to 15 nm thick, or may be about 10 nm thick. A second layer made from barium of about 2.5 to 6.5 nm in thickness may cover the silver layer and be in contact with the electroluminescent organic materials 28. The barium layer may also be about 3 to 4 nm thick.

The anode 36 and cathode 40 of the first device 26 may be sandwiched between substrates 42. The substrates 42 may be the same material for the top and bottom of device 26, or different materials may be selected. Generally, two classes of materials may be used for the substrates 42, inorganic materials and organic materials. Inorganic materials, e.g., glass, may be very transparent and may also provide a barrier layer, preventing oxygen from degrading the organic materials. However, inorganic materials may be brittle (if thick), in flexible, and fragile. To overcome these disadvantages, plastic may be used for the substrates 42. Non-limiting examples of substrates 42 include inorganic glasses, ceramic foils, polymeric materials, filled polymeric materials, coated metallic foils, acrylics, epoxies, polyamides, polycarbonates, polyimides, polyketones, polyoxy-1,4-phenyleneoxy-1,4-phenylenecarbonyl-1,4-phenylene sometimes referred to as polyether ether ketone or (PEEK), polynorbornenes, polyphenyleneoxides, polyethylene naphthalenedicarboxylate (PEN), polyethylene terephthalate (PET), polyether sulfone (PES), polyphenylene sulfide (PPS), and fiber-reinforced plastics (FRP). In one embodiment the substrates 42 may be flexible. Flexible substrates 42 may also be thin metal foils such as stainless steel provided they are coated with an insulating layer to electrically isolate the metal foil from the anode.

If the outermost layers of the multilayer structure 24, for example, the top substrate 42 in the first device 26 or the bottom substrate 42 in the third device 44, are plastic, the barrier properties may be improved to extend the lifespan of the device. For example, a barrier coating may be disposed on any of the outer substrates 42 to prevent moisture and oxygen diffusion through the substrate 42. In certain embodiments, a barrier coating 45 may be disposed or otherwise formed on a surface of the outermost substrate 42 of the top device 26 such that the barrier coating 45 completely covers the substrate 42. In another embodiment, a barrier coating 47 may be deposited on the outermost substrate 42 of the bottommost device 44. The barrier coating 45 on the top layer of substrate 42 may be the same or different than the barrier coating 47 in the bottom layer of substrate 42. Further, either barrier coating 45 or 47 may not be necessary, depending on other materials in the structure. One of ordinary skill in the art will recognize that the barrier coating 45 and 47 may include any suitable reaction or recombination products for reacting species. The barrier coating 45 and 47 may have a thickness ranging from about 10 nm to about 10,000 nm, or in a range from about 10 nm to about 1,000 nm. As will be appreciated by one of ordinary skill in the art, the thickness of the barrier coating 45 and 47 may be selected so as not to impede the transmission of light through the substrate 42, such as a barrier coating 45 and 47 that causes a reduction in light transmission of less than about 20% or less than about 5%. It may also be desirable to choose a barrier coating material and thickness that does not significantly reduce the flexibility of the substrate 42, and whose properties do not significantly degrade with bending.

The barrier coating 45 and 47 may include materials such as, but not limited to, organic material, inorganic material, ceramics, metals, or combinations thereof. Typically, these materials are reaction or recombination products of reacting plasma species that may be deposited on the substrate 42 from the plasma. In certain embodiments, the organic materials may comprise carbon, hydrogen, oxygen and optionally, other minor elements, such as sulfur, nitrogen, silicon, etc., depending on the types of reactants. Suitable reactants that result in organic compositions in the coating are straight or branched alkanes, alkenes, alkynes, alcohols, aldehydes, ethers, alkylene oxides, aromatics, etc., having up to 15 carbon atoms. Inorganic and ceramic coating materials typically comprise oxide, nitride, carbide, boride, oxynitride, oxycarbide, or combinations thereof of elements of Groups IIA, IIIA, IVA, VA, VIA, VIIA, IB, and IIB; metals of Groups IIIB, IVB, and VB, and rare-earth metals. For example, silicon carbide can be deposited onto the substrate 42 by recombination of plasmas generated from silane (SiH4) and an organic material, such as methane or xylene. Silicon oxycarbide can be deposited from plasmas generated from silane, methane, and oxygen or silane and propylene oxide. Silicon oxycarbide also can be deposited from plasmas generated from organosilicone precursors, such as tetraethoxysilane (TEOS), hexamethyldisiloxane (HMDSO), hexamethyldisilazane (HMDSN), or octamethylcyclotetrasiloxane (D4). Silicon nitride can be deposited from plasmas generated from silane and ammonia. Aluminum oxycarbonitride can be deposited from a plasma generated from a mixture of aluminum nitrate and ammonia. Other combinations of reactants, such as metal oxides, metal nitrides, metal oxynitrides, silicon oxide, silicon nitride, silicon oxynitrides may be chosen to obtain a desired coating composition.

In other embodiments, the barrier coating 45 and 47 may comprise hybrid organic/inorganic materials, multilayer, or graded organic/inorganic materials. The organic materials may comprise acrylates, epoxies, epoxyamines, xylenes, siloxanes, silicones, etc. Most metals may also be suitable for the barrier coating 45 and 47 in applications where transparency of the substrate 42 is not required, for example, as the bottom layer in the multilayer structure 24. One of ordinary skill in the art will recognize that the substrate 42 may comprise a composition that incorporates a barrier material to provide a hermetic substrate.

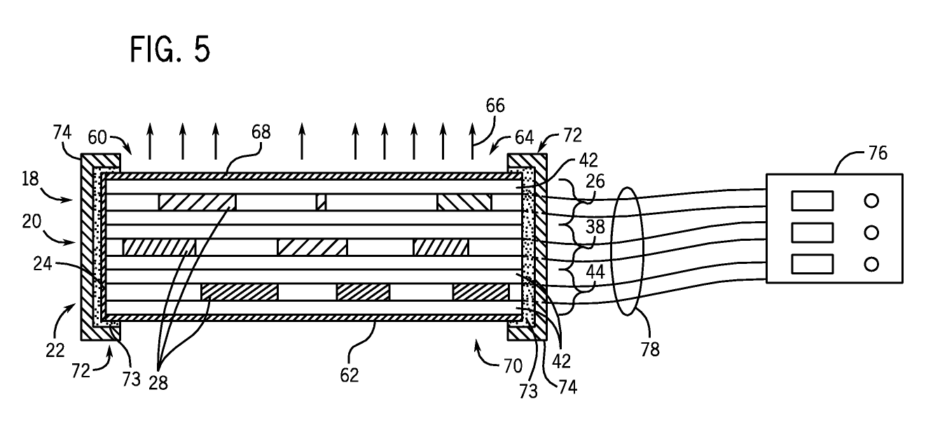

One of ordinary skill in the art will recognize that other barrier layers may be used under the appropriate circumstances. For example, a reflective foil layer attached under the bottom layer of the bottom device (i.e., the third device 44 in FIG. 3), as discussed with respect to FIG. 5, may function as a barrier layer. Further, a thin glass sheet, either optically transparent or somewhat opaque, attached over the top layer of the top device (i.e., the first device 26 in FIG. 3), as discussed with respect to FIG. 5, may also function as a barrier layer.

The second device 38 and third device 44 shown in FIG. 3, and any subsequent devices, may have the same design considerations as discussed above for the first device 26. In FIG. 3, the electrode layers for the second device 38 and the third device 44 are not labeled, but may be selected as for the electrode layers 36 and 40 in the first device 26. Further, these layers may be the same as in the first device 26, or may be independently selected from the materials discussed above.

With respect to the electroluminescent organic materials, subsequent devices may use the same electroluminescent organic materials used in the first device 26, producing the same colors, or may contain different electroluminescent organic materials to produce different colors. For example, in FIG. 3, the second device 38 contains both the first electroluminescent organic material 30, and a third electroluminescent organic material 46. As a further example, the third device 44 may contain a fourth electroluminescent organic material 48.

The devices may be joined together to create a single multilayer structure 24 using any number of possible techniques. For example, the devices may be joined by a connecting layer 48 disposed between the individual devices. The connecting layer 48 may be an optical adhesive, selected to match the refractive index of the materials used in the substrate 42 and, thus, minimize light loss due to reflections at the interfaces between materials. Alternatively, the connecting layer 48 may be an oil with a refractive index matching the substrate 42. In this example, the oil is only used to match the refractive indices, and may not be used for holding the devices together, which may be accomplished by the packaging.

One skilled in the art will recognize that, depending on the materials used in the substrate 42, any number of other techniques may be used to join the devices, including solvent bonding, ultrasonic welding, heat lamination, or any other technique used in the art for joining surfaces. In some embodiments, the devices may be merely held together by the physical packaging, with no oil or other refractive index matching compounds. While this may decrease the efficiency of light transmission from low devices, the loss may not be significant in some applications.

### Production of Devices

An example of a technique that may be used to produce a patterned device in accordance with embodiments of the present techniques may be discussed with respect to FIG. 4. FIG. 4 is a top view of a device 50 showing two patterns 52: “A” and “O.” These patterns 52 are useful for demonstrating the formation of large area patterns having non-illuminated regions 54.

In this figure, a substrate, for example, made from the materials discussed above, has a layer of indium-tin-oxide (ITO) deposited over a top surface to form a bottom electrode (anode, not shown). The bottom electrode may be deposited to form a pattern, but will generally be electrically contiguous throughout the device 50.

The ITO layer, and any of the layers discussed below, may be deposited or disposed using techniques such as, but not limited to, spin coating, dip coating, reverse roll coating, wire-wound or Mayer rod coating, direct and offset gravure coating, slot die coating, blade coating, hot melt coating, curtain coating, knife over roll coating, extrusion, air knife coating, spray, rotary screen coating, multilayer slide coating, coextrusion, meniscus coating, comma and microgravure coating, lithographic process, Langmuir process and flash evaporation, thermal or electron-beam assisted evaporation, vapor deposition, plasma-enhanced chemical-vapor deposition (“PECVD”), radio-frequency plasma-enhanced chemical-vapor deposition (“RFPECVD”), expanding thermal-plasma chemical-vapor deposition (“ETPCVD”), sputtering including, but not limited to, reactive sputtering, electron-cyclotron-resonance plasma-enhanced chemical-vapor deposition (ECRPECVD”), inductively coupled plasma-enhanced chemical-vapor deposition (“ICPECVD”), and combinations thereof.

After the bottom electrode is formed on the substrate, one or more electroluminescent organic materials may be deposited in regions 56 over the bottom electrode, having enough surface area to completely display the patterns 52. The regions 56 of the electroluminescent organic materials may be surrounded by outer regions 58 having electrically neutral, or insulating materials, as discussed above, or the outer regions 58 may light activated, as discussed above. After additional electroluminescent organic materials are deposited over the bottom electrode, a top electrode 60 having patterned regions, as shown, may be formed.

The top electrode (cathode) may be made from the barium/silver layers, as discussed with respect to FIG. 3, above, or may be made from other materials. The top electrode may be deposited to form the patterns 52, with no top electrode materials deposited in non-illuminated regions 54. In all cases, the top electrode, as shown in FIG. 4, is electrically contiguous, forming a single electric circuit in the device 50. After the top electrode is formed, the substrate surface having the top electrode may be placed over the top of the electroluminescent organic materials on the bottom electrode, with the patterns 52 placed in contact with the regions 56 having the electroluminescent organic materials. In other devices, the top electrode may be deposited directly over the electroluminescent organic materials, after which a cover is affixed over the top electrode, e.g., using a clear adhesive. This technique is discussed further with respect to the examples, below.

Once the device 50 is assembled, leads may be joined to the individual electrode layers. The device may then be joined with other devices in a stacked arrangement to form the final multilayer structure 24 as described and illustrated with respect to FIG. 3.

### Systems Using Multilayer Panels

After the individual devices (for example, 26, 38, and 44) have been joined together (e.g., stacked), the multilayer structure 24 may be made into a final display system 60, an example of which is shown in the cross section of FIG. 5. In FIG. 5, the multilayer structure 24 may have a reflective layer 62 placed underneath the structure to reflect light toward the front face 64 where it is emitted (as indicated by reference numeral 66). A diffuser panel 68 may be located on the front face to scatter the light from the individual devices, blending light emitted from the different layers of electroluminescent organic materials, for example 18, 20, and 22.

The final display system 60 may be hermetically sealed to prevent oxygen infiltration from damaging the electroluminescent organic materials 28, extending the lifespan of the final display system 60. For example, as discussed above with respect to FIG. 3, a substrate 42 may have a barrier layer 45,47 impregnated into a surface. If this is done for the substrate 42 of the front face 64 and the rear face 70 of the multilayer structure 24, this may protect the electroluminescent organic materials 28. Alternatively, if the rear face 70 has a reflective layer 62 attached, for example, made of a metal foil, this reflective layer 62 may provide sufficient protection from moisture and oxygen infiltration. Materials that are suitable for the metal foil may include aluminum foil, stainless steel foil, copper foil, tin, Kovar, Invar, and similar materials. Similarly, a diffuser panel 68 attached to the front face 64 of the multilayer structure 24 may be made from glass or other impregnable materials and, thus, provide sufficient protection for the electroluminescent organic materials 28 without further treatment of the substrates 42 of the multilayer structure 24.

While the techniques discussed above may protect the electroluminescent organic materials 28 from diffusion of oxygen through the front face 64 or rear face 70 of the multilayer structure 24, diffusion of oxygen from the edge 72 of the multilayer structure 24 may still degrade the electroluminescent organic materials 28. Accordingly, the edge 72 may be sealed to prevent this infiltration. Any number of techniques may be used to seal the edge of the panel. For example, an impermeable adhesive 73 may be used to seal the structure, such as a silicon RTV compound, a polyurethane, a polyimide, an epoxy, a polyacrylamide, or any similar sealant or combination of sealants. These may be used in neat form or may be filled by the addition of impermeable fillers, such as, for example, glass particles, metal particles, and the like The fillers may also include getters, such as CaO, among others, which may adsorb any excess water molecules present during assembly. Further, a plastic edging 74 may be placed around the edges 72 of the multilayer structure 24, which may be held in place and sealed by the impermeable adhesive. One of ordinary skill in the art will recognize that any number of other techniques may be used to seal the edges of the multilayer structure 24. For example, a metal alloy sealant may be disposed about the entire perimeter of the device 60 such that the electroluminescent organic materials are completely surrounded by the metal alloy sealant 60. Generally, such a metal alloy sealant may include adhesive materials that may be employed to couple together the substrates 42 in each device or join all three devices together, thereby completely enclosing the multilayer structure 24. One of ordinary skill in the art will recognize that any combination of these techniques may be used. For example, a plastic edging 74 may be layered over a metal alloy sealant, and held in place by an impermeable adhesive.

The final display system 60 may be connected to a controller 76 by electrical lines 78 connected to the individual anodes and cathodes (not shown) of each device 26, 38, and 42. The controller 76 may individually energize each device, individually displaying the design 18, 20, or 22 contained therein. Alternatively, the controller may be configured to power each device 26, 38, or 42 either simultaneously with other devices so that one or more of the designs 18, 20, and 22 are concurrently visible. One of ordinary skill in the art will recognize that the current applied to each device 26, 38, or 42 may be controlled to change the amount of illumination provided by the device 26, 38, or 42. For example, this could be used to generate other effects, such as illuminating “open” or “closed” signs on a sign containing a business logo. Furthermore, this could be used to adjust the sign illumination for the ambient lighting conditions, making the sign more visible during bright conditions.

### Examples of Sample Devices

Sample structures were constructed to test the current carrying capacity of the silver/barium layers of the present techniques, and to demonstrate the transparency that may be achieved using this type of construction. Each structure was independently fabricated, as discussed below.

A first set of structures was prepared having a glass substrate with an indium tin oxide (ITO) layer of approximately 100 nm in thickness. A glass substrate having a deposited layer of ITO was purchased from Applied Films (now Applied Materials of Santa Clara, Calif.). The ITO layer was about 100 nm thick, and was electrically contiguous. The structures were prepared by sputtering a layer of silver over the ITO. After the silver layer was deposited, a layer of barium of about 3 nm in thickness was sputtered over the layer of silver. Another set of structures was prepared using a glass substrate without any ITO deposited. The various layers and thicknesses used are shown in Table 1, below

TABLE 1
TEST STRUCTURES FOR DETERMINING LAYER
PROPERTIES

| | FILM THICKNESS (nm) | | |
|---|---|---|---|
| Structure | | | Indium-Tin- |
| No. | Barium | Silver | Oxide (ITO) |
| 1 | 3 | 12 | — |
| 2 | 3 | 12 | 100 |
| 3 | 3 | 20 | — |
| 4 | 3 | 20 | 100 |

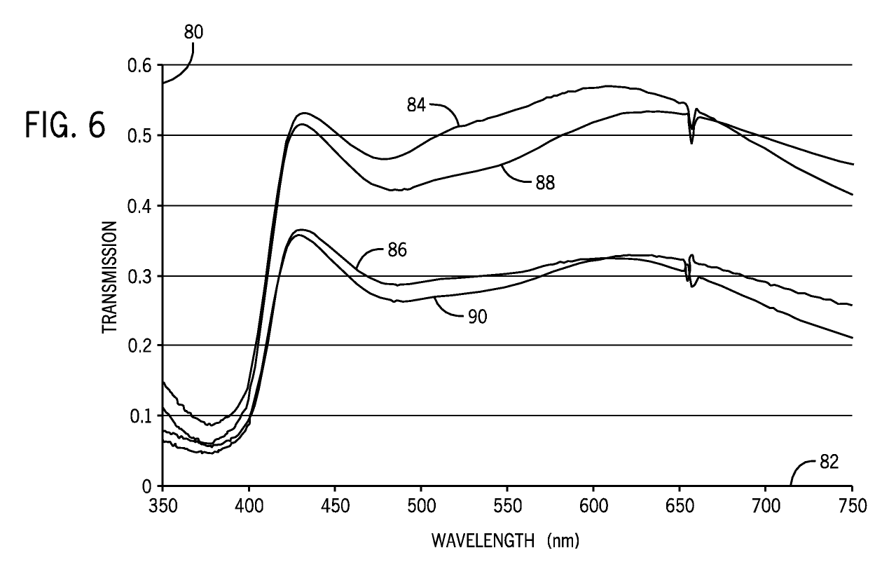

The results obtained for light transmission for these structures is shown in the chart of FIG. 6. In FIG. 6, the y-axis 80 represents the value of light transmission through a structure. The x-axis 82 represents the wavelength of the impinging light in nanometers (nm). As can be seen from the results in this chart, the light transmission is most affected by the thickness of the silver layer. For example, the light transmission of structure no. 1 in Table 1, represented by reference numeral 84, may be compared to the light transmission of device no. 3, represented by reference numeral 86. As can be seen from the results, increasing the thickness of the silver layer from 12 nm to 20 nm may cause a significant drop in light transmission, for example, about 15 percentage points, across much of the spectrum. In comparison to the silver, the addition of a layer of the ITO may have a lesser effect. This may be seen by the comparison between the light transmissions of structure no. 1, indicated by reference numeral 84, with structure no. 2, indicated by reference numeral 88, which may have a difference of less than about 5 percentage points across the spectrum. The small effect of the ITO layer on the transmission may also be seen in the comparison of the light transmission of structure no. 3, indicated by reference numeral 86, with the light transmission of structure no. 4, indicated by reference numeral 90. In this case, the transmission is even closer than for the thinner layers of silver in structure nos. 1 and 2, with less than about a 4 percentage point difference in transmission across the spectrum.

Light emitting devices were made using film structures similar to structure nos. 2 and 4 in Table 1. These devices were then tested to determine the electrical conductivity and light emitting efficiency that may be obtained. Each device was prepared using a glass substrate having a deposited layer of ITO, which was purchased from Applied Films (now Applied Materials of Santa Clara, Calif.). The ITO layer was about 80 nm thick, and was electrically contiguous. The glass substrate with the ITO film was cleaned prior to any further steps. To clean the substrate and film it was first rinsed with deionized (DI) water, then placed in an ultrasonic cleaner with a solution of a commercial detergent, Alconox (available from Alconox, Inc. of White Plains, N.Y.). The substrate and film was then rinsed by further ultrasonication in DI water, followed by drying under a nitrogen stream. As a final step, the substrate and film was ultrasonicated in acetone, then ultrasonicated in propanol, and finally blown dry with nitrogen.

A solution of poly-3,4-ethylene dioxy thiophene (PDOT), (obtained from H.C. Starck. Inc., product name Bayton P VP CH 800) was spin-coated on top of the ITO to form a continuous layer approximately 50-70 nm thick. A layer of another polymer, poly(9,9-dioctyl-fluorene-co-N-(4-butylphenyl)-diphenylamine (TFB), was spin coated over the PDOT to form a layer about 10 nm thick. TFB improves hole injection into the light emitting polymer.

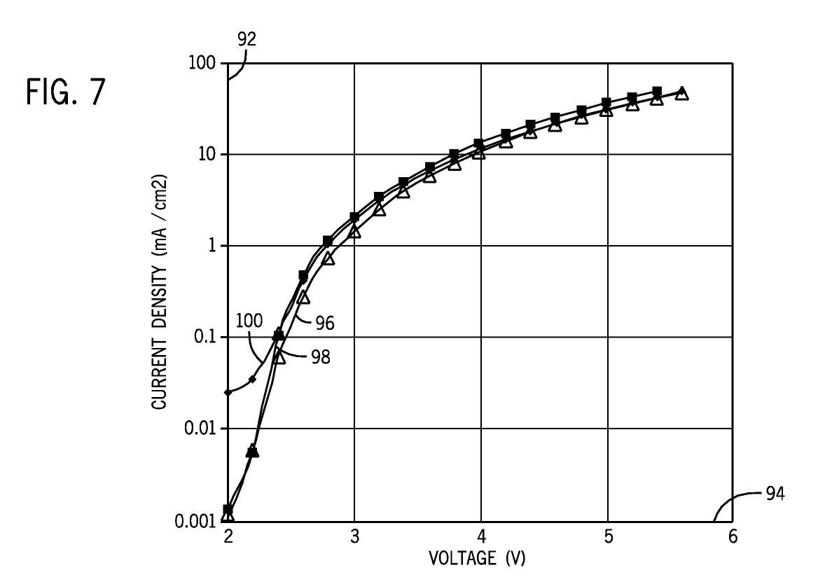

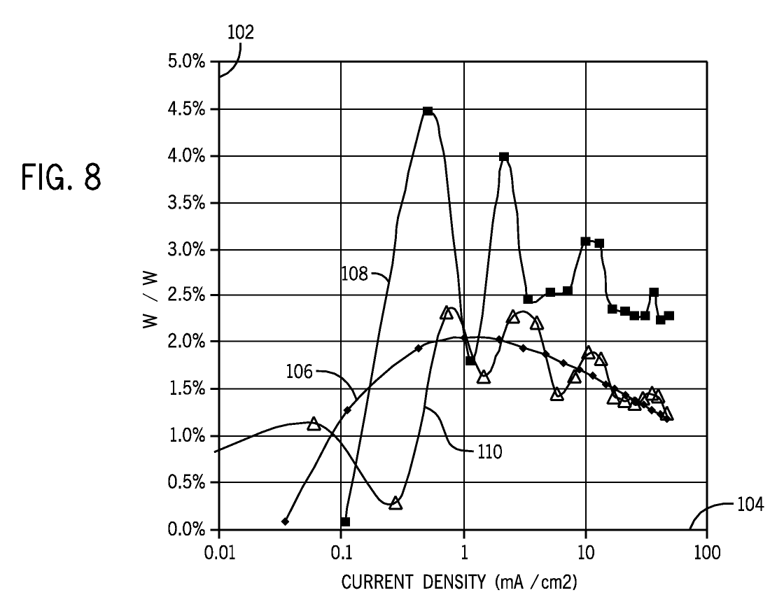

A solution of a light emitting polymer, commercially obtained from Sumation Co. of Tokyo, Japan, was dissolved at 1% concentration (10 milligrams/milliliter) in xylene. A variety of light emitting polymers, in several colors, are commercially available from this source and all will work the same in the construction of devices. Devices were made using blue, green, and red light emitting polymers. However, the results obtained from testing three devices made using a blue light emitting polymer are discussed with respect to FIGS. 7 and 8, below.

The solution of the light emitting polymer was spin coated over the substrate to form a light-emitting layer of about 40 nm to about 80 nm in thickness on top of the PDOT layer. A barium cathode layer of about 3 nm in thickness was then deposited on the light emitting polymer by thermally evaporating the barium and condensing it over the top of the light emitting polymer. A silver layer was deposited on top of the barium layer using the same technique.

The thickness of the silver layer was varied across the three devices tested. A comparison device used a layer of silver of about 100 nm in thickness, while two other devices used silver layers of about 12 nm (in a first device) and 20 nm (in a second device) in thickness. A layer of an ultraviolet light (UV) curable epoxy (such as N68 from Electro-Lite Corporation of Bethel, Conn.) was applied over the silver layer and a glass cover slip was set in place over the UV curable epoxy followed by irradiation with a UV light source to cure the epoxy.

The results for the electrical conductivity of the devices are shown in the chart of FIG. 7. In FIG. 7, the y-axis 92 represents the value of current density that may be carried by a device, in milliamps per square centimeter (mA/cm²). The x-axis 94 represents the voltage (v) at which the measurements were taken. The current density measured for the first device, which had a barium film thickness of about 3 nm and a silver film thickness of about 12 nm, is indicated by reference numeral 96. The current density measured for the second device, which had a barium film thickness of about 3 nm and a silver film thickness of about 20 nm, is indicated by reference numeral 98. The current density for a comparison device made with a 3 nm thick layer of barium over a 100 nm thick layer of silver was also tested, and the results are indicated by reference numeral 100. The results indicate that the current density for all three devices is similar above about 2.5 volts. Above 2.5 volts, device no. 3 has about a 10% lower value for current density than the comparison sample, and device no. 1 has about a 30% lower value for current density than the comparison sample. Below 2.5 volts, however, the thicker silver layer of the comparison sample has a significantly higher current density.

The light emitting efficiencies of the devices made by the method described above are shown in FIG. 8. In FIG. 8, the y-axis 102 represents the light emission efficiency in watts of light emitted per watts of electricity applied. The x-axis 104 represents the current density applied to the device in milliamps per square centimeter (mA/cm²). The light emitting efficiency of the comparison device shows a steady increase as the current density is increased, as indicated by reference numeral 106. In comparison, the second device, as indicated by reference numeral 108, shows some variation in emission efficiency with current density changes, but the overall efficiency may be higher than that of the comparison device. Although the silver layer is thinnest on the first device, at 12 nm, the emission efficiency, as indicated by reference numeral 110, is similar to that of the comparison device having a 100 nm thick silver layer. The variations seen in the curves referenced by numerals 108 and 110 may be attributable to experimental error, either in the measurement of the efficiency or in the formation of the very thin layers in either

While only certain features of the invention have been illustrated and described herein, many modifications and changes will occur to those skilled in the art. It is, therefore, to be understood that the appended claims are intended to cover all such modifications and changes as fall within the true spirit of the invention.

What is claimed is:

1. A light emitting assembly, comprising:
two or more devices joined into a layered structure, wherein each of the two or more devices is configured to be individually illuminated, and wherein each of the two or more devices comprises:
a bottom electrode, wherein the bottom electrode is electrically contiguous;
a layer comprising one or more electroluminescent organic materials in electrical contact with the bottom electrode; and
a top electrode, wherein the top electrode is electrically contiguous and in electrical contact with the layer, wherein at least one of the bottom electrode, a component of the layer, or the top electrode is physically or chemically patterned to form a design configured to be illuminated.

2. The light emitting assembly of claim 1, wherein each of the two or more devices is configured to emit light at a different color.

3. The light emitting assembly of claim 1, wherein each of the two or more devices is configured to emit light at the same color.

4. The light emitting assembly of claim 1, wherein any one of the two or more devices is configured to simultaneously emit light at different colors.

5. The light emitting assembly of claim 1, wherein the design in each of the two or more devices is different from the design in every other one of the two or more devices.

6. The light emitting assembly of claim 1, wherein the design in each of the two or more devices comprises information in a different language.

7. The light emitting assembly of claim 1, wherein the bottom electrode in each of the two or more devices comprises a layer of indium-tin-oxide that is between about 10 and about 100 nm in thickness.

8. The light emitting assembly of claim 1, wherein the top electrode in each of the two or more devices comprises a layer of silver that is between about 5 and about 15 nm in thickness.

9. The light emitting assembly of claim 1, wherein the top electrode in each of the two or more devices comprises a layer of barium that is between about 1 nm and about 7 nm in thickness.

10. The light emitting assembly of claim 1, wherein any one of the two or more devices transmits greater than about 30% of light having a wavelength between about 475 nm and 750 nm.

11. The light emitting assembly of claim 1, wherein the electroluminescent organic materials comprise at least one electroluminescent polymer or electroluminescent polymer derivative that is selected from the group consisting of polyfluorene, poly (phenylene vinylene), and poly (vinyl carbazole).

12. The light emitting assembly of claim 1, wherein the electroluminescent organic materials comprise organometallic compounds.

13. The light emitting assembly of claim 1, wherein each of the two or more devices comprises a flexible substrate.

14. The light emitting assembly of claim 1, wherein the layer in any one of the two or more devices comprises one or more of a hole transport layer, a hole injection layer, an electron transport layer, or an electron injection layer.

15. The light emitting assembly of claim 1, comprising one or more flexible substrates.

16. The light emitting assembly of claim 1, comprising
a lower device joined to a bottom surface of the layered structure, wherein the lower device is configured to be individually illuminated, and wherein the lower device comprises:
a layer comprising one or more electroluminescent organic materials.

17. A method for manufacturing a display, comprising:
forming two or more light emitting devices, wherein each of the two or more light emitting devices is configured to be individually energized, wherein in each device at least one of an anode, a cathode, or a component of a layer comprising an electroluminescent organic material, is physically or chemically patterned to form a design; and
joining the two or more devices in a vertical fashion to form a multilayer structure.

18. The method of claim 17, comprising forming a hermetically sealed package around the multilayer structure.

19. The method of claim 17, wherein joining the two or more devices in a vertical fashion comprises adhering, laminating, sonic welding, or physically mounting the two or more devices, or any combination thereof.

20. The method of claim 17, comprising mounting the multilayer structure in a bracket, to another object, on a signpost, or any combination thereof.

21. A system comprising:
an electrical control and power unit; and
two or more light emitting layers configured to be independently illuminated by the electrical control and power unit, and wherein each of the two or more light emitting layers comprises:
contiguous;
a layer comprising one or more electroluminescent organic materials in electrical contact with the bottom electrode; and
a top electrode, wherein the top electrode is electrically contiguous and in electrical contact with the layer comprising the electroluminescent organic materials, wherein at least one of the bottom electrode, a component of the layer comprising the electroluminescent organic materials, or the top electrode is physically or chemically patterned to form a design configured to be illuminated.

22. The system of claim 21, wherein the electrical control and power unit is configured to alternately energize each of the two or more light emitting layers.

23. The system of claim 21, wherein any of the two or more light emitting layers is configured to emit more than one color of light.

24. A device, comprising:
a multilayer panel, comprising two or more light emitting layers, wherein each layer of the two or more light emitting layers:
comprises one or more electroluminescent organic materials;
is a single unit that is electrically contiguous across the entire layer; and
has a different design or color with respect to each of the other layers of the two or more light emitting layers; and
a controller providing power to individually energize each layer of the multilayer panel.

25. The device of claim 24, wherein the controller is configured to alternately illuminate each layer of the multilayer panel.
